(19) United States
(12) Patent Application Publication
(10) Pub. No.: US 2004/0108544 A1
(43) Pub. Date: Jun. 10, 2004

(54) High voltage mosfet with laterally varying drain doping and method

(75) Inventors: Zia Hossain, Tempe, AZ (US); Mohamed Imam, Tempe, AZ (US); Joe Fulton, Chandler, AZ (US)

Correspondence Address: James J. Stipanuk, Semiconductor Components Industries, L.L.C., Patent Administration Dept - MD/A700, P.O. Box 62890, Phoenix, AZ, 85082-2890, US

(73) Assignee: Semiconductor Components Industries, LLC

(21) Appl. No.: 10/313,133

(22) Filed: Dec. 9, 2002

(51) Int. Cl. H01L 29/792; H01L 29/76; H01L 29/94; H01L 31/062

(52) U.S. Cl. 257/328; 257/326

(57) ABSTRACT

A transistor (100) is formed on a semiconductor substrate (17) that forms a channel (27) of the transistor. A drain region (25) has a second conductivity type formed in the substrate to electrically couple to the channel. A first portion (40) of the drain region is formed with a first depth and a second portion (61) is formed between the first portion and the channel with a second depth less than the first depth. First and second field reduction regions (10, 11) have a first conductivity type and are formed in the first and second portions of the drain region. The first field reduction region is formed to a third depth and the second field reduction region is formed between the first field reduction region and the channel with a fourth depth less than the third depth.

### BACKGROUND OF THE INVENTION

The present invention relates in general to semiconductor devices and more specifically to high voltage lateral-diffused-metal-oxide-semiconductor (LDMOS) transistors.

Many applications use switching transistors in their power supplies in order to increase efficiency. Often, the applications require that the switching transistors withstand high voltage levels. LDMOS transistors are used in some applications because their planar structure allows for easy integration on a semiconductor die with other circuitry.

A problem with existing LDMOS transistors is their high on-resistance, i.e., the resistance of the transistor when it is turned on. The on-resistance results in power being dissipated in the transistor, which reduces the efficiency of the system. Some previous transistors are formed to have a low on-resistance, but their breakdown voltage typically is reduced to a level inadequate for most applications. Part of the on-resistance depends on the doping or charge concentration in the drain of the transistor, so that if the doping is increased, the on-resistance decreases. However, increased doping also results in a lower breakdown voltage, which prevents the devices from being used in some applications.

One approach to increase the breakdown voltage is to reduce the strength of the electric field at the surface of the drain region of the transistor using a reduced surface field technique (RESURF). For an n-channel transistor, RESURF involves doping the n-type drain region to have a charge concentration approaching a maximum of 1.0*10¹² atoms/centimeter² in a thin vertical slice of the drain region. This area charge concentration in units of atoms/centimeter² is equal to the volume doping concentration in units of atoms/centimeter³ integrated over a predetermined interval. Some existing transistors extend the RESURF technique by forming a p-type region within the drain region, called a double RESURF technique, so the n-type drain region is sandwiched between the p-type region and a p-type substrate. Double RESURF allows for a higher doping concentration and a charge concentration approaching 2.0*10¹² atoms/centimeter² in the drain region, which effectively reduces the transistor's on-resistance and maintains generally the same breakdown voltage. With double RESURF used today, the limit of improvement of on-resistance is a charge concentration approaching 2.0*10¹² atoms/centimeter².

Hence, there is a need for a switching transistor and method of providing a low on-resistance without reducing the breakdown voltage in order to provide a high efficiency in an application.

### BRIEF DESCRIPTION OF THE DRAWINGS

FIG. 1 is a cross-sectional view of the transistor;

FIG. 2 is a cross-sectional view of the transistor in a first alternate embodiment;

FIG. 3 is a cross-sectional view of the transistor in a second alternate embodiment.

### DETAILED DESCRIPTION OF THE DRAWINGS

In the figures, elements having the same reference number have similar functionality.

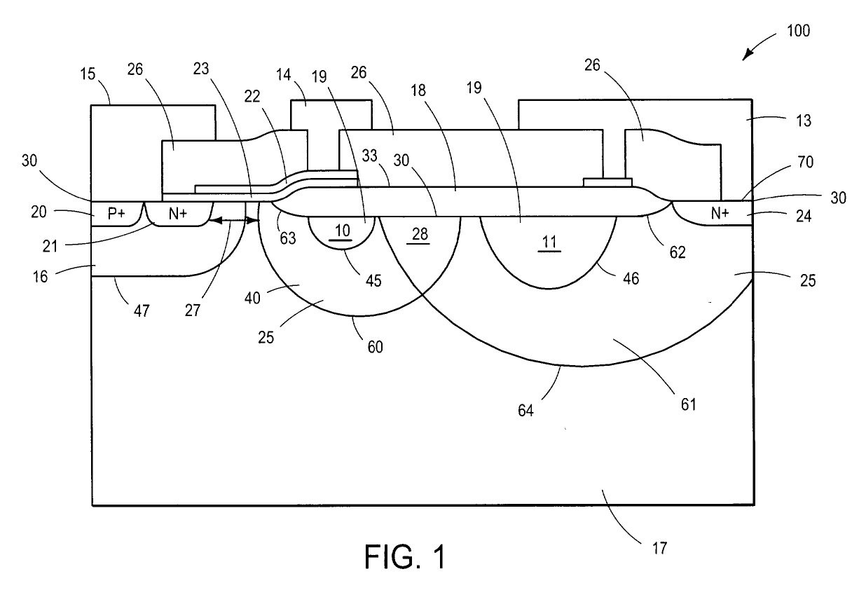

FIG. 1 shows a cross-sectional view of a lateral-diffused-metal-oxide-semiconductor (LDMOS) power transistor 100 formed on a semiconductor substrate 17 for use in a switching regulator. In one embodiment, transistor 100 operates with a drain to source and drain to gate breakdown voltage of greater than seven hundred volts. Transistor 100 has a source region 21 and a drain region 25 for electrically coupling to a channel 27. Source region 21, drain region 25 and channel 27 are all formed at a surface 30 of substrate 17 to facilitate the addition of other circuitry (not shown) in order to form an integrated circuit that contains transistor 100.

Semiconductor substrate has p-type conductivity and a high resistivity. In one embodiment, semiconductor substrate 17 is lightly doped to provide a high breakdown voltage with a doping concentration in a range of about 1.0*10¹⁴ and 2.0*10¹⁴ atoms/centimeter³.

An implanted well region 16 is formed in substrate 17 to form channel 27 at surface 30. Well region 16 typically is doped with a surface concentration of about 2.0*10¹⁷ atoms/centimeter³ and formed to a depth of about 2.5 micrometers below surface 30. The p-type dopants increase the conduction threshold of channel 27 in order to increase noise immunity and prevent false triggering of transistor 100. Well region 16 is called a high voltage P region (PHV), because it provides an additional benefit of reducing device susceptibility to high voltage punch-through between drain region 25 and source region 21.

A well contact region 20 is formed within well region 16 and is highly doped with the same conductivity type to provide an ohmic contact to well region 16. In one embodiment, region 20 has a surface concentration of about 5.0*10¹⁸ atoms/centimeters³ and a depth of about 0.8 micrometers below surface 30. Region 20 also reduces device susceptibility to parasitic bipolar effects.

A source region 21 is formed within well region 16 to make electrical contact to channel 27. In one embodiment, source region 21 is implanted with n-type dopants to have a concentration of about 1.0*10²⁰ atoms/centimeter³ and is formed to a depth of about 0.8 micron below surface 30.

A source terminal 15 is formed with a standard semiconductor metallization material to electrically connect regions 20 and 21 to maintain them at the same potential. In one embodiment, source terminal 15 is biased at ground potential.

A region 24 is formed within the drain region 25 and is heavily doped to provide an ohmic contact for externally connecting a voltage to drain region 25. The voltage is applied to drain region 25 through a metal drain terminal 13 via a drain contact 70 and region 24. Region 24 has the same conductivity type as drain region 25.

A dielectric layer 18 is formed over drain region 25 to a thickness, in one embodiment, of 1.2 micrometers. In another embodiment, dielectric layer 18 comprises a thermally grown silicon dioxide resulting in a first bird's beak formation 62 and a second bird's beak formation 63. In another embodiment, dielectric layer 18 may be formed using a deposited oxide. It should be noted that the drain region 25 underlies both the first and second bird's beak formations 62, 63, and the drain region 25 is closer to the channel 27 than the second bird's beak 63.

A gate dielectric layer 23 is formed over channel 27. In one embodiment, gate dielectric layer 23 is made of silicon dioxide grown to a thickness of 600 angstroms at surface 30.

A gate 22 is formed over gate dielectric layer 23 to function as a control electrode that controls the conductivity of channel 27. In one embodiment, gate 22 is formed with polycrystalline silicon. The gate 22 is electrically connected via a metal region referred to as a gate terminal 14 formed over and electrically contacting gate dielectric layer 23. Note that gate 22 extends over a portion of field oxide region 18 a distance in order to redistribute the electric field.

Drain region 25 includes first and second drain portions 40 and 61, respectively, of an n-type conductivity that form junctions 60 and 64, respectively, with semiconductor substrate 17. The drain region 25 includes an overlapping portion 28 of the first drain portion 40 and the second drain portion 61.

A field reduction structure is designated as a p-top region 19, which includes p-top regions 10 and 11, formed at surface 30. P-top region 19 is doped with a p-type conductivity to form junctions 45 and 46 respectively, with the drain region 25. The depth of the first drain portion 40 is greater than the depth of p-top region 10, and the depth of the second drain portion 61 is greater than the depth of p-top region 11. The doping and depths of p-top regions 10 and 11 are discussed in further detail below. Note that in the embodiment shown in FIG. 1, p-top regions 10 and 11 are formed within first and second drain portions 40 and 61, respectively, and are not connected to each other. In an alternate embodiment, p-top regions 10 and 11 may overlap. In yet a further embodiment, p-top region 19 may be formed as a continuously laterally graded region.

The charge concentration of drain portion 40 is selected so that a charge of up to about 2.0*10¹² atoms/centimeter² is contained in a thin vertical slice from the bottom of drain portion 40 to the bottom of p-top region 10. In one embodiment, this vertical charge concentration is implemented with an n-type doping with a peak surface concentration of about 1.5*10¹⁶ atoms/centimeter³ and an overall junction depth of about nine micrometers. The depth of drain region 40 is selected to fully deplete this charge to surface 30 at a first predetermined drain voltage. Similarly, the charge concentration of drain portion 61 is selected so that a charge of up to about 4.0*10¹² atoms/centimeter² is contained in a thin vertical slice from the bottom of drain portion 61 to the bottom of p-top region 11. In one embodiment, this vertical charge concentration is implemented with an n-type doping with a peak surface concentration of about 4*10¹⁶ atoms/centimeter³ and an overall junction depth of about twelve micrometers. The depth of drain region 61 is selected to fully deplete this charge to surface 30 at a second, higher, predetermined drain voltage. In one embodiment, the first predetermined drain voltage is about two hundred volts and the second drain voltage is about seven hundred volts. Note that drain portions 40 and 61 are formed with different depths and different peak surface concentrations.

The different depths and doping concentrations of drain portions 40 and 61 may be formed by any of a variety of processing methods. For example, regions 40 and 61 may be formed using separate masking steps with separate implant steps. More economically, the different depths and doping concentrations can be formed by delivering dopants through different sized masking apertures using the same masking and implant processes. For example, dopants may be introduced through a mask opening having a width of one micrometer to form region 40, while the dopants are delivered through a larger opening, e.g., with a fifteen micrometer width, to form region 61. Since more total dopants are introduced through the larger opening, region 61 has a higher doping concentration and diffuses to a greater depth than region 40. This approach is readily extended at a low cost to produce a continuously graded lateral doping concentration and a continuously increasing depth from one end of the drain region to the other. Field reduction region 19 can be formed in a similar fashion. With a suitable selection of aperture widths, a lateral doping profile for drain region 25 and/or field reduction region 19 can, if desired, be generally linearly graded and/or can be formed with a generally linearly increasing depth with distance from channel 27.

Yet other alternative processes may be used to form regions 40 and 61. For example, a dielectric mask may be etched to varying thicknesses using a series of masking steps. During the subsequent implant, the different thicknesses will block different amounts of dopant, thereby laterally varying the number of dopants.

The doping concentration of p-top region 10 is selected so that 1.0*10¹² atoms/centimeter² of charge are contained in a thin vertical slice of p-top region 10. The depth is selected to fully deplete this charge to surface 30 at the first predetermined drain voltage, which, in one embodiment, is about two hundred volts. Similarly, the doping concentration of p-top region 11 is selected so that 2.0*10¹² atoms/centimeter² of charge are contained in a thin vertical slice. The depth of p-top region 11 is selected to fully deplete this charge to surface 30 at the second, higher, predetermined drain voltage of about seven hundred volts.

P-top regions 10 and 11 are formed with different depths. In on embodiment, p-top region 10 has a depth of about 2 micrometers, while p-top region 11 has a depth of about 3.5 micrometers. P-top region 10 is more lightly doped than p-top region 11, with a peak concentration of about 3.0*10¹⁶ atoms/centimeter³ as compared to a peak concentration of about 6.0*10¹⁶ atoms/centimeter³ for p-top region 11. The above doping profiles of drain portions 40 and 61 and p-top regions 10 and 11 are an embodiment in which drain 25 is said to be charge balanced. In general, charge balanced structures are those in which the p-top regions are formed to have about one-half the charge of their corresponding drain portions, with substrate 17 providing the remainder of the depletion charge that provides the charge balance. The drain region 25 sandwiched between the substrate 17 and the p-top region 19 can provide a maximum charge on the drain region 25 of 4.0*10¹² atoms/centimeter², which generally reduces the on-resistance.

An interlayer dielectric region 26 (ILD) covers a portion of gate 22, gate dielectric layer 23, dielectric layer 18 and region 24 as shown, and is opened for electrically contacting source terminal 15, gate terminal 14 and drain terminal 13. Also, the ILD 26 provides protection for the transistor 100.

The operation of transistor 100 in the off state and with a direct current (DC) drain voltage V_{D} proceeds as follows. Assume source region 21 and gate 22 are operating at ground potential and drain voltage V_{D}=2000.0 volts is applied to drain terminal 13. Then well region 16 and region 20 also are at ground potential, which reverse biases junctions 60 and 64. The doping profile of drain portion 40 is selected to fully deplete that region to surface 30, which has the effect of setting the potential of p-top region 10 to about two hundred volts. Drain portion 61 is only partially depleted.

Now assume V_{D} is increased from two hundred volts to seven hundred volts. Regions 11 and 61 will continue to deplete and fully deplete at seven hundred volts. Drain portion 40 remains fully depleted and p-top region 10 remains at a potential of about two hundred volts. Drain portion 61 now fully depletes to surface 30 and p-top region 11 operates at about seven hundred volts of potential. Since drain portion 40 depletes at about two hundred volts, increasing the voltage applied to drain terminal 13 results in at most a minimal increase in the potential to no more than fifty volts near channel 27 and gate dielectric layer 23, preventing breakdown of the gate dielectric layer 23 or the area under the gate dielectric layer 23. This operation results in a high reliability, robust device.

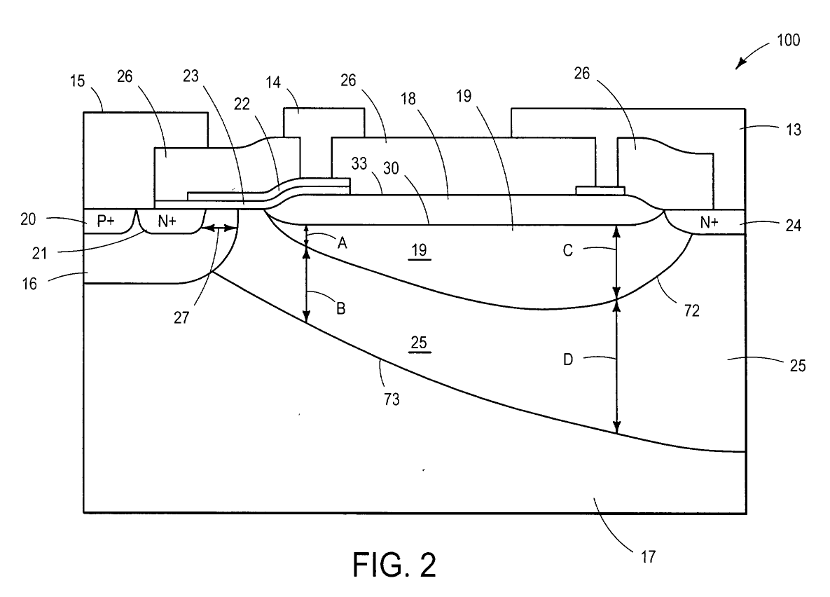

FIG. 2 shows a cross-sectional view of transistor 100 in an alternate embodiment in which the depths and doping concentrations of drain region 25 and p-top region 19 vary in a nearly continuous fashion, using, for example, a multiplicity of mask openings to introduce different amounts of dopants across the lateral dimension of drain region 25 and p-top region 19. In one embodiment, the doping concentrations of both the drain region 25 and the p-top region 19 linearly increase with the distance from the channel 27. Both of these doping concentrations are proportional to the depths of junctions 72, formed by the p-top region 19 with the drain region 25, and 73, formed by the drain region 25 with the substrate 17. A charge balance between the n-type drain region 25 and the p-top region 19 must be maintained to have the RESURF condition. For example, to maintain RESURF, drain region 25 has twice the charge concentration of p-top region 19 as described above.

In the embodiment of FIG. 2, the charge in drain region 25 varies from up to about 2.0*10¹² atoms/centimeter² in vertical slice B up to about 4.0*10¹² atoms/centimeter² in vertical slice D. The charge in p-top region 19 varies from up to about 1.0*10¹² atoms/centimeter² in vertical slice A up to about 2.0*10¹² atoms/centimeter² in vertical slice C. Note that the maximum charge concentration is 4.0*10¹² atoms/centimeter² in the portion of the drain region 25 furthest from the channel 27, which allows a higher doping concentration in drain region 25 and a resulting lower on-resistance.

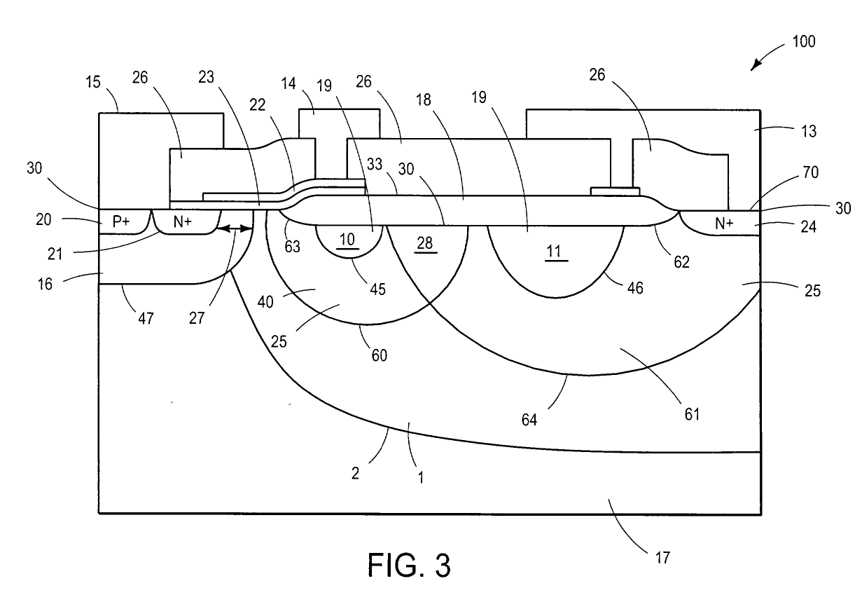

FIG. 3 is a cross-sectional view of transistor 100 in yet another embodiment showing drain region 25 with drain portions 40 and 61, formed in a lightly doped drain region 1. Lightly doped drain region 1 forms a junction 2 with the substrate 17. In one embodiment, the lightly doped drain region 1 has a surface doping concentration of about 3.0*10¹⁵ atoms/centimeter³. The lightly doped region 1 reduces the subsequent diffusion of the first drain portion 40 toward the channel 27 providing breakdown protection in the area near the channel 27. In one embodiment, the lightly doped drain region 1 forms a boundary 47 with well region 16.

In summary, the present invention provides a robust and highly reliable LDMOS transistor at a low cost using standard semiconductor processing. A semiconductor substrate is inverted to form a channel of the transistor. An n-type drain region is formed in the substrate for electrically coupling to the channel. A first portion of the drain region is formed with a first depth and a second portion is formed between the first portion and the channel with a second depth less than the first depth. A field reduction structure having first and second p-top regions are in the first and second portions of the drain region. The first p-top region is formed to a third depth and the second p-top region is formed between the first p-top region and the channel with a fourth depth less than the third depth.

What is claimed is:

1. A transistor, comprising:
a semiconductor substrate for forming a channel of the transistor;
a drain region of a second conductivity type formed in the substrate for electrically coupling to the channel, and having a first portion formed with a first depth and a second portion formed between the first portion and the channel with a second depth less than the first depth; and
first and second field reduction regions of a first conductivity type respectively formed in the first and second portions of the drain region, wherein the first field reduction region is formed to a third depth and the second field reduction region is formed between the first field reduction region and the channel with a fourth depth less than the third depth.

2. The transistor of claim 1, further comprising a drain contact formed at a surface of the semiconductor substrate over the first portion of the drain region.

3. The transistor of claim 1, wherein the drain region and the field reduction region generally linearly increase in doping concentration with the distance from the channel.

4. The transistor of claim 1, further comprising a lightly doped drain region, wherein the first and second drain portions are formed within the lightly doped drain region.

5. The transistor of claim 1, further comprising a gate for controlling a conductivity of the channel.

6. The transistor of claim 5, further comprising an oxide region having a bird's beak formation under the gate.

7. The transistor of claim 6, wherein a distance from the drain region to the channel is less than a distance from the bird's beak to the channel.

8. The transistor of claim 1, further comprising a well region of the first conductivity type formed in the semiconductor substrate to adjust a conduction threshold of the channel.

9. The transistor of claim 8, further comprising a source region formed within the well region for electrically coupling to the channel.

10. The transistor of claim 1, wherein the field reduction region is located at one or more locations within the drain region, wherein the first depth of the drain region is greater than the third depth of the field reduction region and the second depth of the drain region is greater than the forth depth of the field reduction region.

11. The transistor of claim 1, wherein the first and second portions of the drain region overlap.

12. An LDMOS transistor, comprising:
a semiconductor substrate of a first conductivity type having a surface for providing a channel of the transistor;
a drain region formed in the semiconductor substrate for electrically coupling to the channel, wherein the drain region has a second conductivity type with a first portion formed to a first depth and a second portion formed to a second depth less than the first depth; and
a field reduction structure formed within the drain region and having a first conductivity type and a first region formed to a third depth and a second region formed to a fourth depth less than the third depth.

13. The transistor of claim 12, wherein the first and second regions of the field reduction structure are formed within the first and second portions of the drain region, respectively.

14. The transistor of claim 12, wherein the drain region is formed at the surface of the semiconductor substrate.

15. The transistor of claim 12, wherein the field reduction structure is formed at the surface of the semiconductor substrate.

16. The transistor of claim 12, further comprising an overlapping region formed as an intersection of the first and second portions of the drain region.

17. A method of operating a transistor, comprising:
biasing a drain region of the transistor with a first voltage to deplete a first portion of the drain region from a first depth to a first field reduction region; and
biasing the drain region with a second voltage to deplete a second portion of the drain region from a second depth to a second field reduction region, wherein the first voltage is less than the second voltage, the first depth is less than the second depth, and the second field reduction region is deeper than the first field reduction region.

18. The method of claim 17, wherein the step of biasing the drain region with a second voltage includes the step of applying the second voltage through a drain contact formed at a surface of the semiconductor substrate over the first portion of the drain region.

19. The method of claim 17, further comprising the step of applying a control voltage to a gate of the transistor to control a conductivity of a channel.

20. The method of claim 17, further comprising the step of grounding a source region of the transistor.
